(19) United States
(12) Patent Application Publication
(10) Pub. No.: US 2024/0074211 A1
(43) Pub. Date: Feb. 29, 2024

(54) MEMORY DEVICE HAVING 2-TRANSISTOR VERTICAL MEMORY CELL AND MEMORY ELEMENT BETWEEN CHANNEL REGION AND CONDUCTIVE PLATE

(71) Applicant: Micron Technology, Inc., Boise, ID (US)

(72) Inventors: Kamal M. Karda, Boise, ID (US); Chandra Mouli, Boise, ID (US); Haitao Liu, Boise, ID (US); Durai Vishak Nirmal Ramaswamy, Boise, ID (US)

(21) Appl. No.: 18/238,291

(22) Filed: Aug. 25, 2023

Related U.S. Application Data
(60) Provisional application No. 63/402,346, filed on Aug. 30, 2022.

(51) Int. Cl. H10B 63/00; G11C 5/06; H10B 63/10; H10N 70/00

(52) U.S. Cl. CPC H10B 63/34; G11C 5/063; H10B 63/10; H10B 63/845; H10N 70/883

(57) ABSTRACT

Some embodiments include apparatuses and methods of operating the apparatuses. One of the apparatuses includes a conductive region; a memory cell including a memory element, a first portion, a second portion, a dielectric portion, and a third portion; and a data line formed over the second and third portions of the memory cell. The memory element is formed over the conductive region. The first portion is formed over the memory element and includes a first conductive material. The second portion is formed over the first portion and includes a second conductive material. The dielectric portion includes a first side adjacent the memory element, the first portion, and the second portion. The third portion includes a third conductive material and is adjacent a second side of the dielectric portion and separated from the memory element, the first portion, and the second portion by the dielectric portion.

### PRIORITY APPLICATION

This application claims the benefit of priority to U.S. Provisional Application Ser. No. 63/402,346, filed Aug. 30, 2022, which is incorporated herein by reference in its entirety.

### BACKGROUND

Memory devices are widely used in computers and many other electronic items to store information. Memory devices are generally categorized into two types: volatile memory devices and non-volatile memory devices. A memory device usually has numerous memory cells to store information. In a volatile memory device, information stored in the memory cells is lost if supply power is disconnected from the memory device. In a non-volatile memory device, information stored in the memory cells is retained even if supply power is disconnected from the memory device.

The description herein involves volatile memory devices. Most conventional volatile memory devices store information in the form of charge in a capacitor structure included in the memory cell. As demand for device storage density increases, many conventional techniques provide ways to shrink the size of the memory cell in order to increase device storage density for a given device area. However, physical limitations and fabrication constraints may pose a challenge to such conventional techniques if the memory cell size is to be shrunk to a reduced dimension. Further, storing information in the form of charge in some other memory device structures may also face challenges in data retention due in part to leakage of the charge.

### BRIEF DESCRIPTION OF THE DRAWINGS

FIG. 1 shows a block diagram of an apparatus in the form of a memory device including volatile memory cells, according to some embodiments described herein.

FIG. 2 shows a schematic diagram of a portion of a memory device including a memory array of two-transistor (2T) memory cells, according to some embodiments described herein.

FIG. 3 shows the memory device of FIG. 2, including example voltages used during a read operation of the memory device, according to some embodiments described herein.

FIG. 4 shows the memory device of FIG. 2, including example voltages used during a write operation of the memory device, according to some embodiments described herein.

FIG. 5A, FIG. 5B, FIG. 6, FIG. 7, and FIG. 8 show different views of a structure of the memory device of FIG. 2, according to some embodiments described herein.

FIG. 9A, FIG. 9B, and FIG. 9C show different views of a structure of a memory device including multiple decks of memory cells, according to some embodiments described herein.

### DETAILED DESCRIPTION

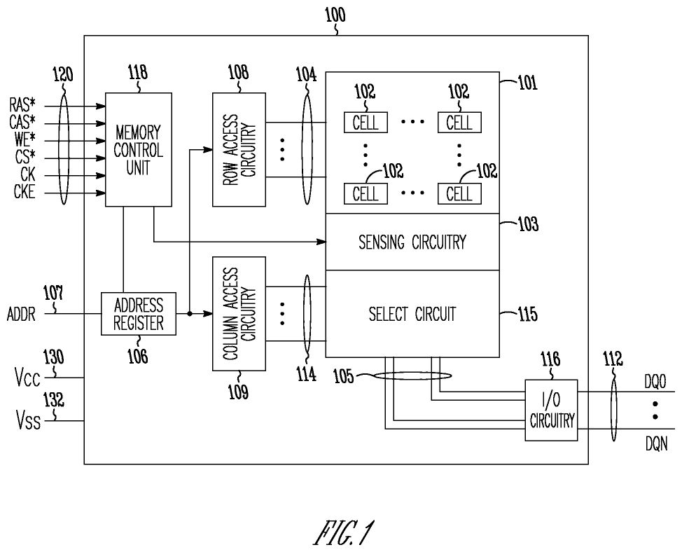

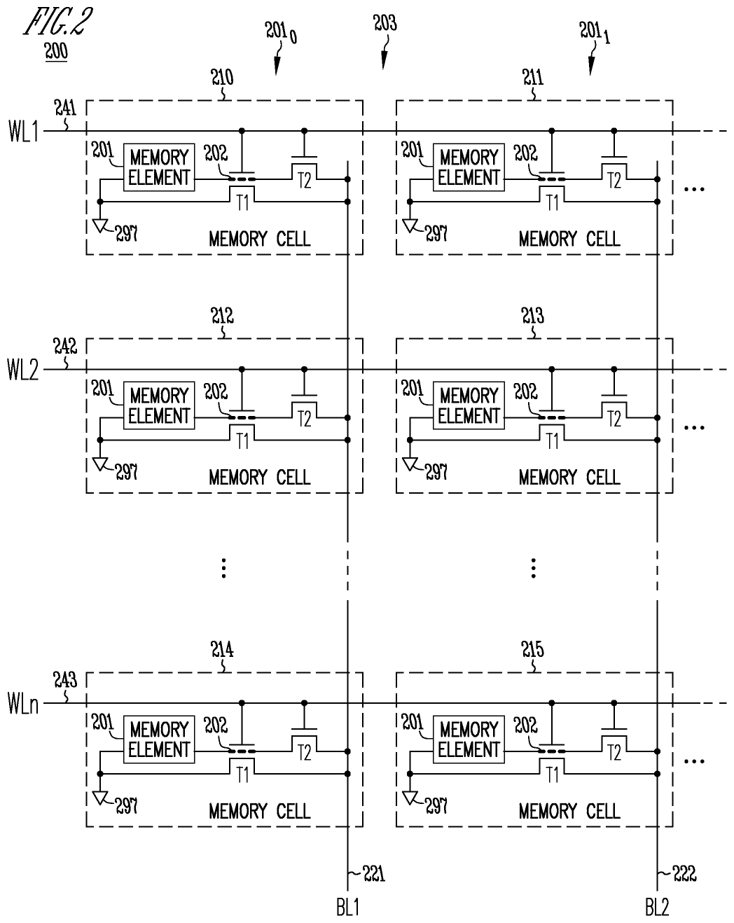

The memory device described herein includes volatile memory cells in which each of the memory cells can include two transistors (2T) and a memory element. The memory element can be configured (e.g., structured) to store information based on the state of memory elements. In an example, the memory element can be configured to have different resistance states. A different resistance state can represent a different value (e.g., digital value) of information stored in the memory element. The described memory device can include a single access line (e.g., word line) to control two transistors of a memory cell. This can lead to reduced power dissipation and improved processing. The memory device described herein can have a structure (e.g., a 4F2 cell footprint) that allows the size of the memory device to be relatively smaller than the size of similar conventional memory devices. Each of the memory cells of the described memory device can include a cross-point gain cell structure (and cross-point operation), such that a memory cell can be accessed using a single access line (e.g., word line) and single data line (e.g., bit line) during an operation (e.g., a read or write operation) of the memory device. Storing information in the form of a state (e.g., a resistance state instead of charge) of the described memory cell having the described memory element can improve retention of information stored in the memory cell. Other improvements and benefits of the described memory device and its variations are discussed below with reference to FIG. 1 through FIG. 9C.

FIG. 1 shows a block diagram of an apparatus in the form of a memory device 100 including volatile memory cells, according to some embodiments described herein. Memory device 100 includes a memory array 101, which can contain memory cells 102. Memory device 100 can include a volatile memory device such that memory cells 102 can be volatile memory cells. An example of memory device 100 includes a dynamic random-access memory (DRAM) device. Information stored in memory cells 102 of memory device 100 may be lost (e.g., invalid) if supply power (e.g., supply voltage Vcc) is disconnected from memory device 100. Hereinafter, supply voltage Vcc is referred to as representing some voltage levels; however, they are not limited to a supply voltage (e.g., Vcc) of the memory device (e.g., memory device 100). For example, if the memory device (e.g., memory device 100) has an internal voltage generator (not shown in FIG. 1) that generates an internal voltage based on supply voltage Vcc, such an internal voltage may be used instead of supply voltage Vcc.

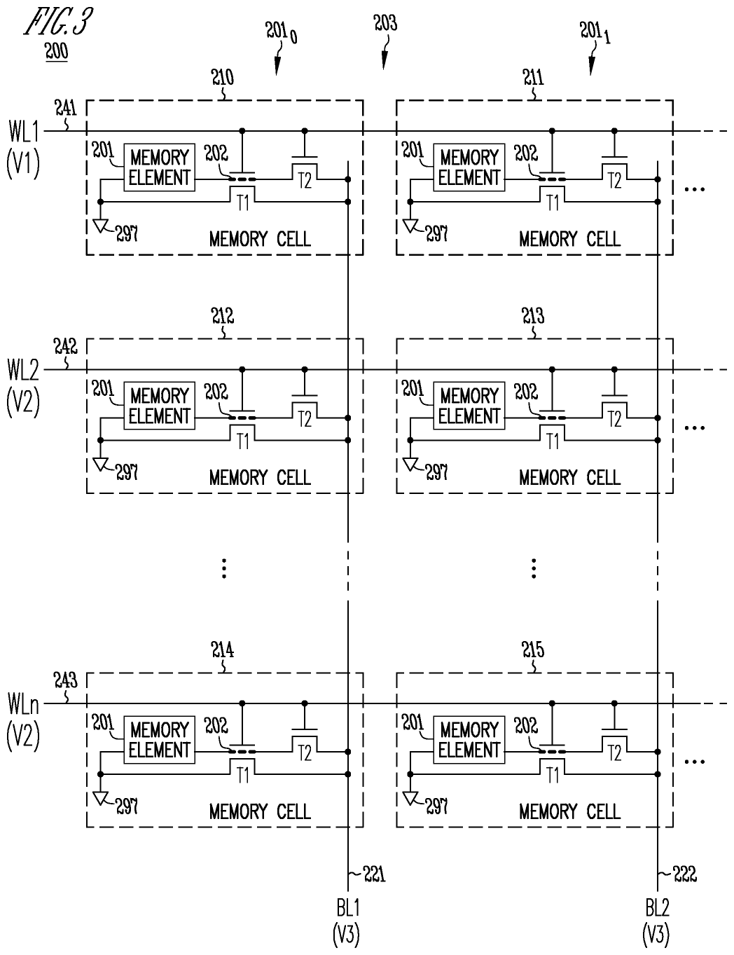

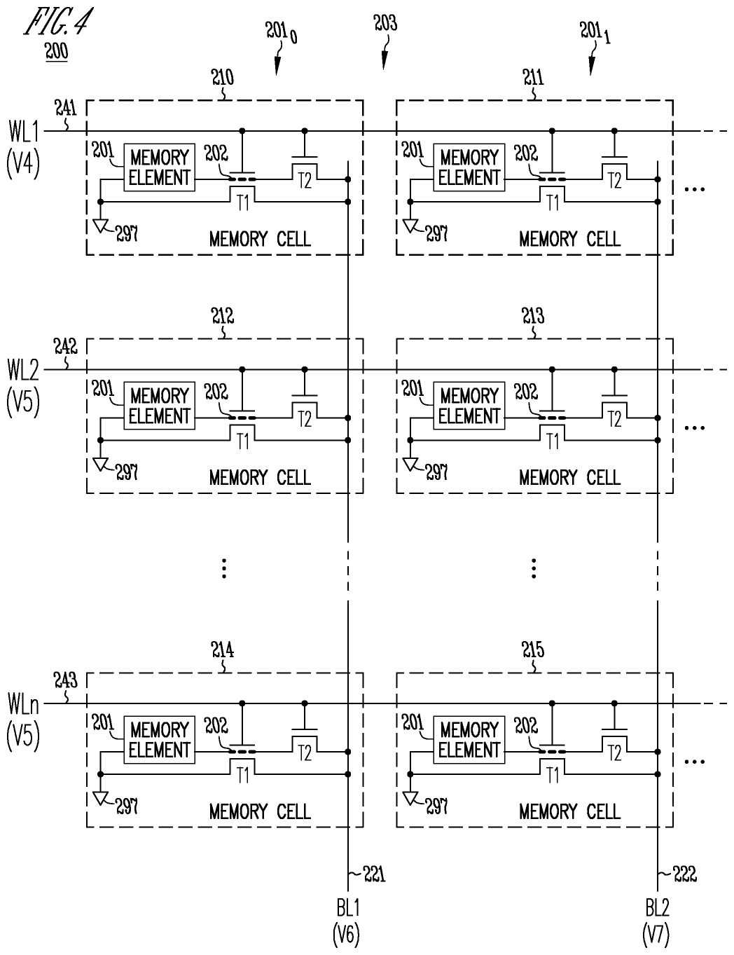

In a physical structure of memory device 100, each of memory cells 102 can include transistors (e.g., two transistors) formed vertically (e.g., stacked on different layers) in different levels over a substrate (e.g., semiconductor substrate) of memory device 100. Memory device 100 can also include multiple levels (e.g., multiple decks) of memory cells where one level (e.g., one deck) of memory cells can be formed over (e.g., stacked on) another level (e.g., another deck) of additional memory cells. The structure of memory array 101, including memory cells 102, can include the structure of memory arrays and memory cells described below with reference to FIG. 2 through FIG. 9C.

As shown in FIG. 1, memory device 100 can include access lines 104 (e.g., “word lines”) and data lines (e.g., bit lines) 105. Memory device 100 can use signals (e.g., word line signals) on access lines 104 to access memory cells 102 and data lines 105 to provide information (e.g., data) to be stored in (e.g., written) or read (e.g., sensed) from memory cells 102.

Memory device 100 can include an address register 106 to receive address information ADDR (e.g., row address signals and column address signals) on lines (e.g., address lines) 107. Memory device 100 can include row access circuitry (e.g., X-decoder) 108 and column access circuitry (e.g., Y-decoder) 109 that can operate to decode address information ADDR from address register 106. Based on decoded address information, memory device 100 can determine which memory cells 102 are to be accessed during a memory operation. Memory device 100 can perform a write operation to store information in memory cells 102, and a read operation to read (e.g., sense) information (e.g., previously stored information) in memory cells 102. Memory device 100 can also perform an operation (e.g., a refresh operation) to refresh (e.g., to keep valid) the value of information stored in memory cells 102. Each of memory cells 102 can be configured to store information that can represent at most one bit (e.g., a single bit having a binary 0 (“0”) or a binary 1 (“1”), or more than one bit (e.g., multiple bits having a combination of at least two binary bits).

Memory device 100 can receive a supply voltage, including supply voltages Vcc and Vss, on lines 130 and 132, respectively. Supply voltage Vss can operate at a ground potential (e.g., having a value of approximately zero volts). Supply voltage Vcc can include an external voltage supplied to memory device 100 from an external power source such as a battery or an alternating current to direct current (AC-DC) converter circuitry.

As shown in FIG. 1, memory device 100 can include a memory control unit 118, which includes circuitry (e.g., hardware components) to control memory operations (e.g., read and write operations) of memory device 100 based on control signals on lines (e.g., control lines) 120. Examples of signals on lines 120 include a row access strobe signal RAS*, a column access strobe signal CAS*, a write-enable signal WE*, a chip select signal CS*, a clock signal CK, and a clock-enable signal CKE. These signals can be part of signals provided to a DRAM device.

As shown in FIG. 1, memory device 100 can include lines (e.g., global data lines) 112 that can carry signals DQ0 through DQN. In a read operation, the value (e.g., “0” or “1”) of information (read from memory cells 102) provided to lines 112 (in the form of signals DQ0 through DQN) can be based on the values of the signals on data lines 105. In a write operation, the value (e.g., “0” or “1”) of information provided to data lines 105 (to be stored in memory cells 102) can be based on the values of signals DQ0 through DQN on lines 112.

Memory device 100 can include sensing circuitry 103, select circuitry 115, and input/output (I/O) circuitry 116. Column access circuitry 109 can selectively activate signals on lines (e.g., select lines) 114 based on address signals ADDR. Select circuitry 115 can respond to the signals on lines 114 to select signals on data lines 105. The signals on data lines 105 can represent the values of information to be stored in memory cells 102 (e.g., during a write operation) or the values of information read (e.g., sensed) from memory cells 102 (e.g., during a read operation).

I/O circuitry 116 can operate to provide information read from memory cells 102 to lines 112 (e.g., during a read operation) and to provide information from lines 112 (e.g., provided by an external device) to data lines 105 to be stored in memory cells 102 (e.g., during a write operation). Lines 112 can include nodes within memory device 100 or pins (or solder balls) on a package where memory device 100 can reside. Other devices external to memory device 100 (e.g., a hardware memory controller or a hardware processor) can communicate with memory device 100 through lines 107, 112, and 120.

Memory device 100 may include other components, which are not shown in FIG. 1 so as not to obscure the example embodiments described herein. At least a portion of memory device 100 (e.g., a portion of memory array 101) can include structures and operations similar to or the same as to any of the memory devices described below with reference to FIG. 2 through FIG. 9C.

FIG. 2 shows a schematic diagram of a portion of a memory device 200 including a memory array 203, according to some embodiments described herein. Memory device 200 can correspond to memory device 100 of FIG. 1. For example, memory array 203 can form part of memory array 101 of FIG. 1. As shown in FIG. 2, memory device 200 can include memory cells 210 through 215, which are volatile memory cells (e.g., DRAM cells). For simplicity, similar or the same elements among memory cells 210 through 215 are given the same labels.

Each of memory cells 210 through 215 can include two transistors T1 and T2 and a memory element 201. Memory element 201 can be configured (e.g., structured) to store information. The value (e.g., digital value) of information stored in a particular memory cell among memory cells 210 through 215 can be based on the state of memory element 201. Memory element 201 can be structured to have different states (e.g., using a write operation). The states can be used to represent different values (e.g., digital value) of information to be stored in memory element 201. For example, the value of information stored in a particular memory cell among memory cells 210 through 215 can be “0” or “1” if each memory element 201 is configured to store a single-bit or “00”, “01”, “10”, “11” or other multi-bit values if memory element 201 is configured to store multiple bits.

In an example, memory element 201 can include a material that can be placed in different resistance states (e.g., using a write operation). The resistance states can be used to represent different values (e.g., digital value) of information to be stored in memory element 201. For example, memory element 201 can have one resistance state (e.g., resistance state R0) to represent information having a value of “0” (binary 0) and another resistance state (e.g., R1) to represent information having a value of “1” (binary 1).

In an example, memory element 201 can include a phase change material, which can include a chalcogenide material or a combination of chalcogenide materials. In this example, the value of information stored in memory element 201 can be based on the resistance state of the phase change material of memory element 201.

In another example, memory element 201 can include ferromagnetic plates (e.g., two ferromagnetic plates), such that memory element 201 can be configured to have different magnetic states (e.g., instead of resistance states) associated with the ferromagnetic plates. In this example, the value of information stored in memory element 201 can be based on magnetic state of memory element 201.

The structures and materials of memory element 201 as described herein are examples. Other structures or materials can be used. For example, memory element 201 can include conductive-bridging random access memory (CBRAM) elements or other types of resistive random-access memory (RRAM) elements.

In FIG. 2, each of memory cells 210 through 215 can be called a 2T memory cell (e.g., 2T gain cell). Each of transistors T1 and T2 can include a field-effect transistor (FET). As an example, transistor T1 can be a p-channel FET (PFET), and transistor T2 can be an n-channel FET (NFET). Part of transistor T1 can include a structure of a p-channel metal-oxide semiconductor (PMOS) transistor. Thus, transistor T1 can include an operation similar to that of a PMOS transistor. Part of transistor T2 can include an n-channel metal-oxide semiconductor (NMOS). Thus, transistor T2 can include an operation similar to that of a NMOS transistor. In another example, both transistors T1 and T2 can be n-channel NFETs.

Transistor T1 of memory device 200 can include floating-gate based structure. As shown in FIG. 2, each of memory cells 210 through 215 can include a conductive portion 202, which is similar to floating gate of transistor T1. However, as described in more detail below, the value of information stored in a particular memory cell of memory device 200 is based on a resistance state of memory element 201 instead of based on the charge stored in the floating gate.

As shown in FIG. 2, transistor T2 (e.g., the channel region of transistor T2) of a particular memory cell among memory cells 210 through 215 can be electrically coupled to (e.g., directly coupled to) conductive portion 202 of that particular memory cell. Thus, a circuit path (e.g., current path) can be formed between transistor T2 of a particular memory cell and memory element 201 through conductive portion 202 of that particular memory cell during an operation (e.g., a write operation) of memory device 200.

Memory cells 210 through 215 can be arranged in memory cell groups 201₀ and 201₁. FIG. 2 shows two memory cell groups (e.g., 201₀ and 201₁) as an example. However, memory device 200 can include more than two memory cell groups. Memory cell groups 201₀ and 201₁ can include the same number of memory cells. For example, memory cell group 201₀ can include memory cells 210, 212, and 214, and memory cell group 201₁ can include memory cells 211, 213, and 215. FIG. 2 shows three memory cells in each of memory cell groups 201₀ and 201₁ as an example. The number of memory cells in memory cell groups 201₀ and 201₁ can be different from three.

Memory device 200 can perform a write operation to store information in memory cells 210 through 215, and a read operation to read (e.g., sense) information from memory cells 210 through 215. Memory device 200 can be configured to operate as a DRAM device. However, unlike some conventional DRAM devices that store information in a structure such as a container for a capacitor or in a floating gate of a transistor, memory device 200 can store information in the form of a resistance state in memory element 201.

As shown in FIG. 2, memory device 200 can include access lines (e.g., word lines) 241, 242, and 243 that can carry respective signals (e.g., word line signals) WL1, WL2, and WLn. During an operation (e.g., a read or write operation) of memory device 200, an access line (e.g., a single access line) and a data line (e.g., a single data line) can be used to access a selected memory cell (e.g., target memory cell). Access lines 241, 242, and 243 can be used to access both memory cell groups 201₀ and 201₁. In the physical structure of memory device 200, each of access lines 241, 242, and 243 can be structured as (can be formed from) at least one conductive line (one conductive line or multiple conductive lines where the multiple conductive lines can be electrically coupled (e.g., shorted) to each other). Access lines 241, 242, and 243 can be selectively activated (e.g., activated one at a time) during an operation (e.g., read or write operation) of memory device 200 to access a selected memory cell (or selected memory cells) among memory cells 210 through 215. A selected cell can be referred to as a target memory cell. In a read operation, information can be read from a selected memory cell (or selected memory cells). In a write operation, information can be stored in a selected memory cell (or selected memory cells).

In memory device 200, a single access line (e.g., a single word line) can be used to control (e.g., turn on or turn off) transistors T1 and T2 of a respective memory cell during either a read or write operation of memory device 200. Some conventional memory devices may use multiple (e.g., two separate) access lines to control access to a respective memory cell during read and write operations. In comparison with such conventional memory devices (that use multiple access lines for the same memory cell), memory device 200 uses a single access line (e.g., shared access line) in memory device 200 to control both transistors T1 and T2 of a respective memory cell to access the respective memory cell. This technique can save space and simplify operation of memory device 200. Further, some conventional memory devices may use multiple data lines to access a selected memory cell (e.g., during a read operation) to read information from the selected memory cell. In memory device 200, a single data line (e.g., data line 221 or 222) can be used to access a selected memory cell (e.g., during a read operation) to read information from the selected memory cell. This may also simplify the structure, operation, or both of memory device 200 in comparison with conventional memory devices use multiple data lines to access a selected memory cell.

In memory device 200, the gate of each of transistors T1 and T2 can be part of a respective access line (e.g., a respective word line). As shown in FIG. 2, the gate of each of transistors T1 and T2 of memory cell 210 can be part of access line 241. The gate of each of transistors T1 and T2 of memory cell 211 can be part of access line 241. For example, in the structure of memory device 200, four different portions of a conductive material (or materials) that form access line 241 can form the gates (e.g., four gates) of transistors T1 and T2 of memory cell 210 and the gates of transistors T1 and T2 of memory cell 211, respectively.

The gate (not labeled in FIG. 2) of each of transistors T1 and T2 of memory cell 212 can be part of access line 242. The gate of each of transistors T1 and T2 of memory cell 213 can be part of access line 242. For example, in the physical structure of memory device 200, four different portions of a conductive material (e.g., four different portions of continuous piece of metal or polysilicon) that forms access line 241 can form the gates (e.g., four gates) of transistors T1 and T2 of memory cell 212 and the gates of transistors T1 and T2 of memory cell 213, respectively.

The gate of each of transistors T1 and T2 of memory cell 214 can be part of access line 243. The gate of each of transistors T1 and T2 of memory cell 215 can be part of access line 243. For example, in the physical structure of memory device 200, four different portions of a conductive material (e.g., four different portions of a continuous piece of metal or polysilicon) that forms access line 243 can form the gates (e.g., four gates) of transistors T1 and T2 of memory cell 214 and the gates of transistors T1 and T2 of memory cell 215, respectively.

In this description, a material can include a single material or a combination of multiple materials. A conductive material can include a single conductive material or combination of multiple conductive materials.

Memory device 200 can include data lines (e.g., bit lines) 221 and 222 that can carry respective signals (e.g., bit line signals) BL1 and BL2. During a read operation, memory device 200 can use data line 221 to obtain information read (e.g., sensed) from a selected memory cell of memory cell group 201₀, and data line 222 to read information from a selected memory cell of memory cell group 201₁. During a write operation, memory device 200 can use data line 221 to provide information to be stored in a selected memory cell of memory cell group 201₀, and data line 222 to provide information to be stored in a selected memory cell of memory cell group 201₁.

Memory device 200 can include a ground connection (e.g., ground plate) 297 coupled to each of memory cells 210 through 215. Ground connection 297 can be structured from a conductive plate (e.g., a layer of conductive material) that can be coupled to ground terminal (e.g., ground plate) of memory device 200.

As shown in FIG. 2, transistor T1 (e.g., the channel region of transistor T1) of a particular memory cell among memory cells 210 through 215 can be electrically coupled to (e.g., directly coupled to) ground connection 297 and electrically coupled to (e.g., directly coupled to) a respective data line (e.g., data line 221 or 222). Thus, a circuit path (e.g., current path) can be formed between a respective data line (e.g., data line 221 or 222) and ground connection 297 through transistor T1 of a selected memory cell during an operation (e.g., a read operation) performed on the selected memory cell.

Memory device 200 can include read paths (e.g., circuit paths). Information read from a selected memory cell during a read operation can be obtained through a read path coupled to the selected memory cell. In memory cell group 201₀, a read path of a particular memory cell (e.g., memory cell 210, 212, or 214) can include a current path (e.g., read current path) through a channel region of transistor T1 of that particular memory cell, data line 221, and ground connection 297. In memory cell group 201₁, a read path of a particular memory cell (e.g., memory cell 211, 213, or 215) can include a current path (e.g., read current path) through a channel region of transistor T1 of that particular memory cell, data line 222, and ground connection 297. In the example where transistor T1 is a PFET (e.g., a PMOS), the current in the read path (e.g., during a read operation) can include a hole conduction (e.g., hole conduction in the direction from data line 221 to ground connection 297 through the channel region (e.g., p-channel region) of transistor T1. Since transistor T1 can be used in a read path to read information from the respective memory cell during a read operation, transistor T1 can be called a read transistor and the channel region of transistor T1 can be called a read channel region.

Memory device 200 can include write paths (e.g., circuit paths). Information to be stored in a memory element 201 of a selected memory cell during a write operation can be provided to the selected memory cell through a write path coupled to the selected memory cell. In memory cell group 201₀, a write path of a particular memory cell can include transistor T2 (e.g., can include a write current path through a channel region of transistor T2 and conductive portion 202) of that particular memory cell and data line 221. In memory cell group 201₁, a write path of a particular memory cell (e.g., memory cell 211, 213, or 215) can include transistor T2 (e.g., can include a write current path through a channel region of transistor T2 and conductive portion 202) of that particular memory cell and data line 222. In the example where transistor T2 is an NFET (e.g., NMOS), the current in a write path (e.g., during a write operation) can include an electron conduction (e.g., electron conduction in the direction from data line 221 to memory element 201 through conductive portion 202) through the channel region of transistor T2. Since transistor T2 can be used in a write path to store information in a respective memory cell (e.g., store in memory element 201) during a write operation, transistor T2 can be called a write transistor and the channel region of transistor T1 can be called a write channel region.

Each of transistors T1 and T2 can have a threshold voltage (Vt). Transistor T1 has a threshold voltage Vt1. Transistor T2 has a threshold voltage Vt2. The values of threshold voltages Vt1 and Vt2 can be different (unequal values). For example, the value of threshold voltage Vt2 can be greater than the value of threshold voltage Vt1.

During a read operation of memory device 200, only one memory cell of the same memory cell group can be selected at a time to read information from the selected memory cell. For example, memory cells 210, 212, and 214 of memory cell group 201₀ can be selected one at a time during a read operation to read information from the selected memory cell (e.g., one of memory cells 210, 212, and 214 in this example). In another example, memory cells 211, 213, and 215 of memory cell group 201₁ can be selected one at a time during a read operation to read information from the selected memory cell (e.g., one of memory cells 211, 213, and 215 in this example).

During a read operation, memory cells of different memory cell groups (e.g., memory cell groups 201₀ and 201₁) that share the same access line (e.g., access line 241, 242, or 243) can be concurrently selected (or alternatively can be sequentially selected). For example, memory cells 210 and 211 can be concurrently selected during a read operation to read (e.g., concurrently read) information from memory cells 210 and 211. Memory cells 212 and 213 can be concurrently selected during a read operation to read (e.g., concurrently read) information from memory cells 212 and 213. Memory cells 214 and 215 can be concurrently selected during a read operation to read (e.g., concurrently read) information from memory cells 214 and 215.

The value of information read from the selected memory cell of memory cell group 201₀ during a read operation can be determined based on the value of a current detected (e.g., sensed) from a read path (described above) that includes data line 221, transistor T1 of the selected memory cell (e.g., memory cell 210, 212, or 214), and ground connection 297. The value of information read from the selected memory cell of memory cell group 201₁ during a read operation can be determined based on the value of a current detected (e.g., sensed) from a read path that includes data line 222, transistor T1 of the selected memory cell (e.g., memory cell 211, 213, or 215), and ground connection 297.

Memory device 200 can include detection circuitry (not shown) that can operate during a read operation to detect (e.g., sense) a current (e.g., current I1, not shown) on a read path that includes data line 221, and detect a current (e.g., current I2, not shown) on a read path that includes data line 222. The value of the detected current can be based on the value of information stored in the selected memory cell. For example, depending on the value of information stored in the selected memory cell of memory cell group 201₀, the value of the detected current (e.g., the value of current I1) on data line 221 can be zero or greater than zero. Similarly, depending on the value of information stored in the selected memory cell of memory cell group 201₁, the value of the detected current (e.g., the value of current I2) on data line 222 can be zero or greater than zero. Memory device 200 can include circuitry (not shown) to translate the value of a detected current into the value (e.g., “0”, “1”, or a combination of multi-bit values) of information stored in the selected memory cell.

During a write operation of memory device 200, only one memory cell of the same memory cell group can be selected at a time to store information in the selected memory cell. For example, memory cells 210, 212, and 214 of memory cell group 201₀ can be selected one at a time during a write operation to store information in the selected memory cell (e.g., one of memory cell 210, 212, and 214 in this example). In another example, memory cells 211, 213, and 215 of memory cell group 201₁ can be selected one at a time during a write operation to store information in the selected memory cell (e.g., one of memory cell 211, 213, and 215 in this example).

During a write operation, memory cells of different memory cell groups (e.g., memory cell groups 201₀ and 201₁) that share the same access line (e.g., access line 241, 242, or 243) can be concurrently selected. For example, memory cells 210 and 211 can be concurrently selected during a write operation to store (e.g., concurrently store) information in memory cells 210 and 211. Memory cells 212 and 213 can be concurrently selected during a write operation to store (e.g., concurrently store) information in memory cells 212 and 213. Memory cells 214 and 215 can be concurrently selected during a write operation to store (e.g., concurrently store) information in memory cells 214 and 215.

Information to be stored in a selected memory cell of memory cell group 201₀ during a write operation can be provided through a write path (described above) that includes data line 221 and transistor T2 of the selected memory cell (e.g., memory cell 210, 212, or 214). Information to be stored in a selected memory cell of memory cell group 201₁ during a write operation can be provided through a write path (described above) that includes data line 222 and transistor T2 of the selected memory cell (e.g., memory cell 211, 213, or 215). As described above, the value (e.g., binary value) of information stored in a particular memory cell among memory cells 210 through 215 can be based on the state (e.g., resistance state) of memory element 201 of that particular memory cell.

In a write operation, the state (e.g., resistance state) of memory element 201 of a selected memory cell can be changed (to reflect the value of information stored in the selected memory cell) by applying a voltage on a write path that includes transistor T2 of that particular memory cell and the data line (e.g., data line 221 or 222) coupled to that particular memory cell. For example, a voltage having one value (e.g., 0V) can be applied on data line 221 (e.g., provide 0V to signal BL1) if information to be stored in a selected memory cell among memory cells 210, 212, and 214 has one value (e.g., “0”). In another example, a voltage having another value (e.g., a positive voltage) can be applied on data line 221 (e.g., provide a positive voltage to signal BL1) if information to be stored in a selected memory cell among memory cells 210, 212, and 214 has another value (e.g., “1”). Thus, information can be stored in a memory element 201 of a particular memory cell by providing the information to be stored (e.g., in the form of a voltage) on a write path (that includes transistor T2) of that particular memory cell.

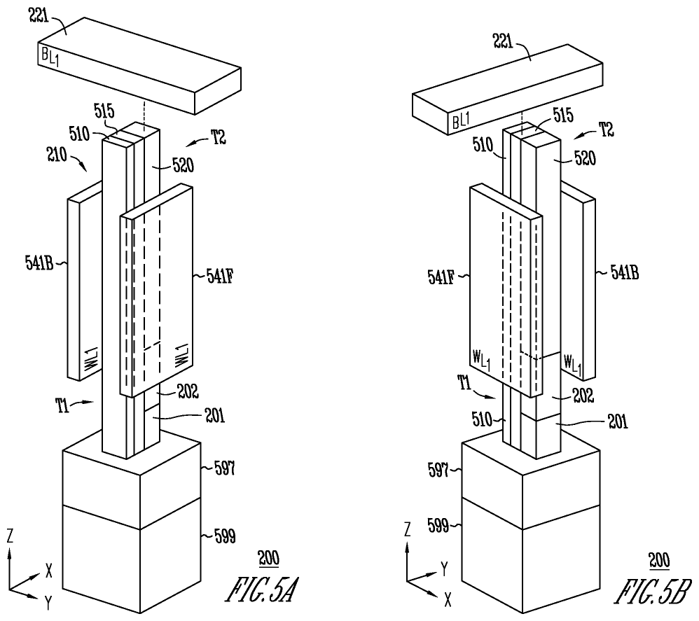

FIG. 3 shows memory device 200 of FIG. 2 including example voltages V1, V2, and V3 used during a read operation of memory device 200, according to some embodiments described herein. The example of FIG. 3 assumes that memory cells 210 and 211 are selected memory cells (e.g., target memory cells) during a read operation to read (e.g., to sense) information stored (e.g., previously stored) in memory cells 210 and 211. Memory cells 212 through 215 are assumed to be unselected memory cells. This means that memory cells 212 through 215 are not accessed, and information stored in memory cells 212 through 215 is not read while information is read from memory cells 210 and 211 in the example of FIG. 3. In this example, access line 241 can be called a selected access line (e.g., selected word line), which is the access line associated with (e.g., coupled to) selected memory cells (e.g., memory cells 210 and 211 in this example). In this example, access lines 242 and 243 can be called unselected access lines (e.g., unselected word line), which are the access lines associated with (e.g., coupled to) unselected memory cells (e.g., memory cells 212, 213, 214, and 215 in this example).

In FIG. 3, voltages V1, V2, and V3 can represent different voltages applied to respective access lines 241, 242, and 243 and data lines 221 and 222 during a read operation of memory device 200. Voltage V1 can be applied to the selected access line (e.g., access line 241). In a read operation, voltage V2 can be applied to the unselected access lines (e.g., access lines 242 and 243).

Voltages V1, V2, and V3 can have different values. As an example, voltages V1, V2, and V3 can have values −1V, 0V, and 0.5V, respectively. The specific values of voltages used in this description are only example values. Different values may be used. For example, voltage V1 can have a range from −3V to 3V.

In the read operation shown in FIG. 3, voltage V1 can have a value (voltage value) to turn on transistor T1 of each of memory cells 210 and 211 (selected memory cells in this example) and turn off (or keep off) transistor T2 of each of memory cells 210 and 211. This allows information to be read from memory cells 210 and 211. Voltage V2 can have a value, such that transistors T1 and T2 of each of memory cells 212 through 215 (unselected memory cells in this example) are turned off (e.g., kept off). Voltage V3 can have a value, such that a current (e.g., read current) may be formed on a read path that includes data line 221 and transistor T1 of memory cell 210, and a read path (a separate read path) that includes data line 222 and transistor T1 of memory cell 212. This allows a detection of current on the read paths (e.g., on respective data lines 221 and 222) coupled to memory cells 210 and 211, respectively. A detection circuitry (not shown) of memory device 200 can operate to translate the value of the detected current (during reading of information from the selected memory cells) into the value (e.g., “0”, “1”, or a combination of multi-bit values) of information read from the selected memory cell. In the example of FIG. 3, the value of the detected currents on data lines 221 and 222 can be translated into the values of information read from memory cells 210 and 211, respectively.

In the read operation shown in FIG. 3, the voltages applied to respective access lines 241, 242, and 243 can cause transistors T1 and T2 of each of memory cells 212 through 215 to turn off (or to remain turned off). Transistor T1 of memory cell 210 (selected memory cell) may or may not turn on, depending on the value of the threshold voltage Vt1 of transistor T1 of memory cell 210. Transistor T1 of memory cell 211 (selected memory cell) may or may not turn on, depending on the value of the threshold voltage Vt1 of transistor T1 of memory cell 211. For example, if transistor T1 of each of memory cells (e.g., 210 through 215) of memory device 200 is configured (e.g., structured) such that the threshold voltage of transistor T1 is less than zero (e.g., Vt1<−1V), then transistor T1 of memory cell 210, in this example, can turn on (e.g., fully turn on) and conduct a current on data line 221 (through transistor T1 of memory cell 210). In this example, transistor T1 of memory cell 211 can also turn on and conduct a current on data line 222 (through transistor T1 of memory cell 211).

In the read operation described above, transistor T2 of memory cell 210 (selected memory cell) turns off (or remains turned-off) or may partially turn on depending on the resistance state of the memory element 201 of memory cell 210. A relatively small amount of current may flow between data line 221 and ground connection 297 through transistor T2, conductive portion 202, and memory element 201 of memory cell 210. However, the resistance state of memory element 201 of memory cell 210 remains unchanged. Thus, the value of information stored in memory element 201 of memory cell 210 remains unchanged during a read operation.

Similarly, in the above example read operation, transistor T2 of memory cell 211 (selected memory cell) turns off (or remains turned-off) or may partially turn on depending on the resistance state of the memory element 201 of memory cell 211. A relatively small amount of current may flow between data line 222 and ground connection 297 through transistor T2, conductive portion 202, and memory element 201 of memory cell 211. However, the resistance state of memory element 201 of memory cell 211 remains unchanged. Thus, the value of information stored in memory element 201 of memory cell 211 remains unchanged.

In the example read operation described above, memory device 200 can determine the value of information stored in memory cells 210 and 211 based on the value of the currents on data lines 221 and 222, respectively. As described above, memory device 200 can include detection circuitry to measure the value of currents on data lines 221 and 222 during a read operation.

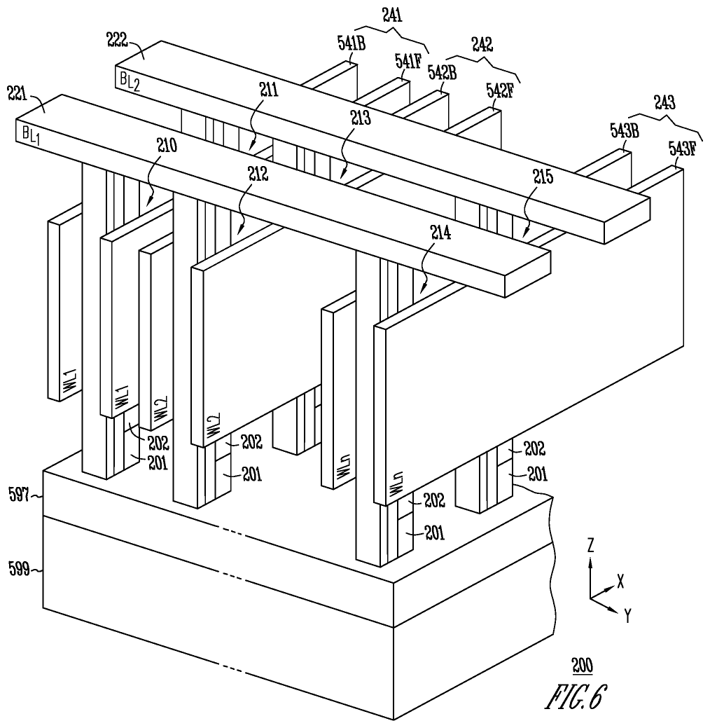

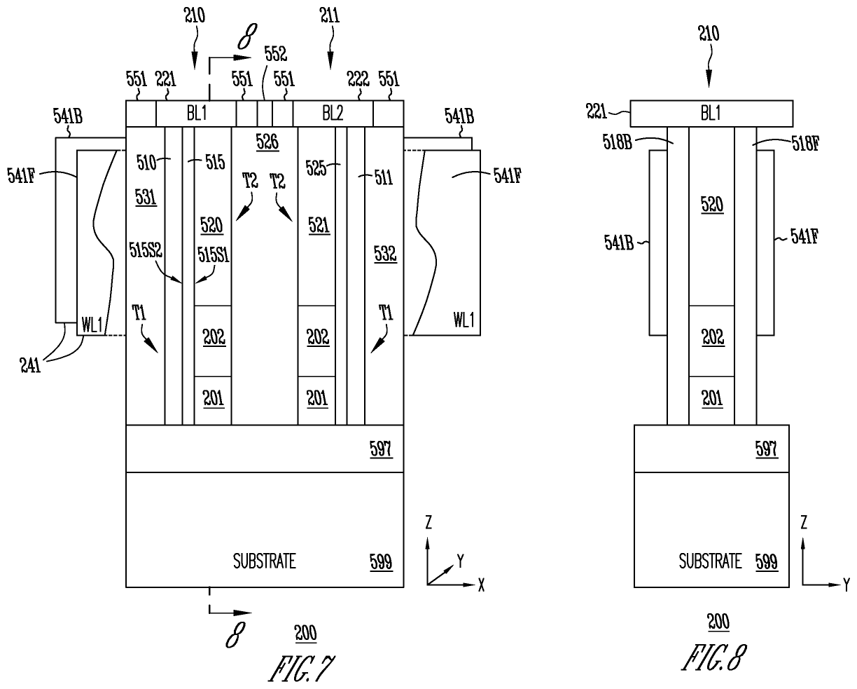

FIG. 4 shows memory device 200 of FIG. 2 including example voltages V4, V5, V6, and V7 used during a write operation of memory device 200, according to some embodiments described herein. The example of FIG. 4 assumes that memory cells 210 and 211 are selected memory cells (e.g., target memory cells) during a write operation to store information in memory cells 210 and 211. Memory cells 212 through 215 are assumed to be unselected memory cells. This means that memory cells 212 through 215 are not accessed and information is not to be stored in memory cells 212 through 215 while information is stored in memory cells 210 and 211 in the example of FIG. 4.

In FIG. 4, voltages V4, V5, V6, and V7 can represent different voltages applied to respective access lines 241, 242, and 243 and data lines 221 and 222 during a write operation of memory device 200. In a write operation, voltage V4 can be applied to the selected access line (e.g., access line 241). Voltage V5 can be applied to the unselected access lines (e.g., access lines 242 and 243).

Voltages V4 and V5 can have different values. As an example, voltages V4 and V5 can have values of 3V and 0V, respectively. These values are example values. Different values may be used. For example, voltage V4 can have a range from −3V to 3V.

The values of voltages V6 and V7 can be the same or different depending on the value (e.g., “0” or “1”) of information to be stored in memory cells 210 and 211. For example, the values of voltages V6 and V7 can be the same (e.g., V6=V7) if the memory cells 210 and 211 are to store information having the same value. As an example, V6=V7=0V if information to be stored in each memory cell 210 and 211 is “0”. In another example, V6=V7=V+ (e.g., V+ is a positive voltage (e.g., from 1V to 3V)) if information to be stored in each memory cell 210 and 211 is “1”.

In another example, the values of voltages V6 and V7 can be different (e.g., V6 V7) if the memory cells 210 and 211 are to store information having different values. As an example, V6=0V if “0” is to be stored in memory cell 210, and V7=V+(e.g., V+ is a positive voltage (e.g., from 1V to 3V)) if “1” is to be stored in memory cell 211. As another example, V6=V+(e.g., V+ is a positive voltage (e.g., from 1V to 3V)) if “1” is to be stored in memory cell 210, and V7=0V if “0” is to be stored in memory cell 211.

The range of voltage of 1V to 3V is used here as an example. A different range of voltages can be used. Further, instead of applying 0V (e.g., V6=0V or V7=0V) to a particular write data line (e.g., data line 221 or 222) for storing information having a value of “0” to the memory cell (e.g., memory cell 210 or 211) coupled to that particular write data line, a positive voltage (e.g., V6>0V or V7>0V) may be applied to that particular data line.

In a write operation of memory device 200 of FIG. 4, voltage V5 can have a value (e.g., V5=0V or V5<0V), such that transistors T1 and T2 of each of memory cells 212 through 215 (unselected memory cells, in this example) are turned off (e.g., kept off). Voltage V4 can have a value (e.g., V4>0V) to turn on transistor T2 of each of memory cells 210 and 211 (selected memory cells in this example) and form a write path between data line 221 and memory element 201 of memory cell 210 through transistor T2 and conductive portion 202 of memory cell 210, and a write path between data line 222 and memory element 201 of memory cell 211 through transistor T2 and conductive portion 202 of memory cell 210. A current (e.g., write current) may be formed between conductive portion 202 of memory cell 210 (selected memory cell) and data line 221.

The example write operation described above can cause the resistance state of memory element 201 of memory cell 210 to reflect the value of information to be stored in memory cell 210. The example write operation can cause the resistance state of memory element 201 of memory cell 211 to change to reflect the value of information to be stored in memory cell 210.

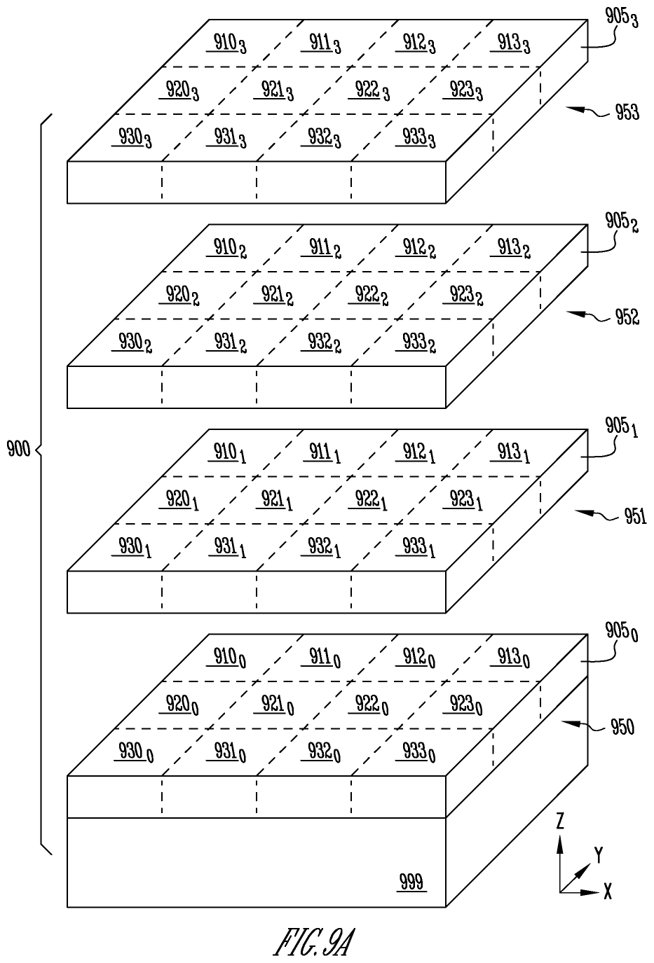

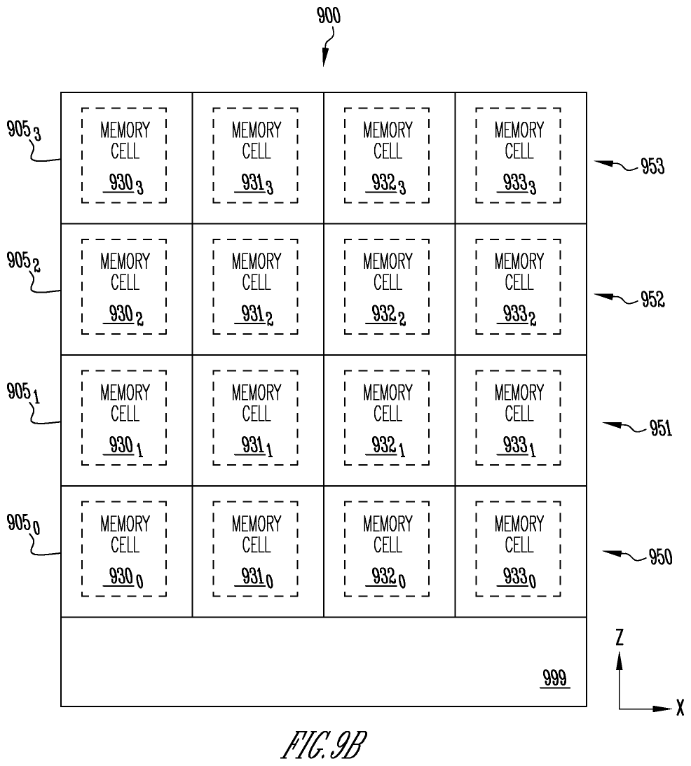

FIG. 5A, FIG. 5B, FIG. 6, FIG. 7, and FIG. 8 show different views of a structure of memory device 200 of FIG. 2 with respect to the X, Y, and Z directions, according to some embodiments described herein. FIG. 5A, FIG. 5B and FIG. 6 show different 3-dimensional views (e.g., isometric views) of memory device 200 with respect to the X-Y, and Z directions. FIG. 7 shows a side view (e.g., cross-sectional view) of memory device 200 with respect to the X-Z direction. FIG. 8 shows a view (e.g., cross-sectional view) with respect to the Y-Z direction taken along lines 8-8 of FIG. 7.

For simplicity, FIG. 5A and FIG. 5B show the structure of memory cell 210. The structures of other memory cells (e.g., memory cells 211 through 215) of memory device 200 of FIG. 2 can be similar to or the same as the structure of memory cell 210 shown in FIG. 5A and FIG. 5B. In FIG. 2 and FIG. 5A through FIG. 8, the same elements are given the same reference numbers.

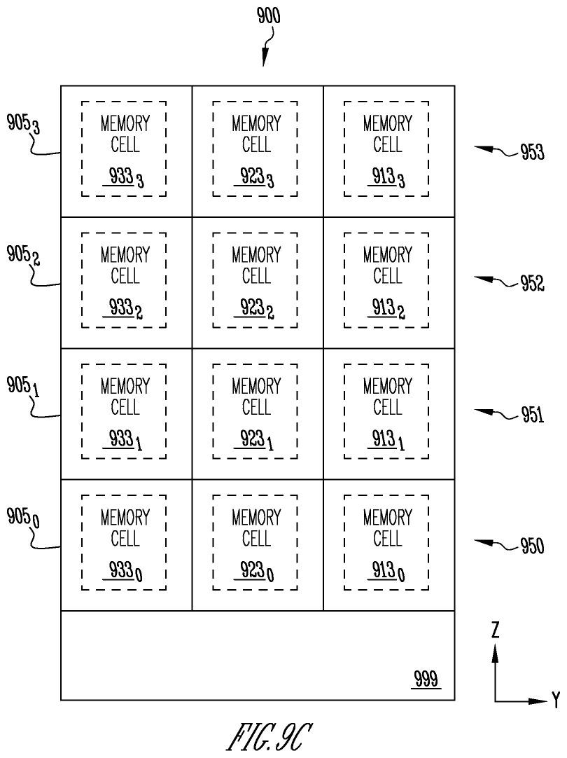

The following description refers to FIG. 5A through FIG. 8. For simplicity, detailed description of the same element is not repeated in the description of FIG. 5A through FIG. 8. Also for simplicity, cross-sectional lines (e.g., hatch lines) are omitted from most of the elements shown in FIG. 5A through FIG. 8 and other figures (e.g., FIG. 9 through FIG. 9C) in the drawings described herein. Some elements of memory device 200 may be omitted from a particular figure of the drawings so as to not obscure the description of the element (or elements) being described in that particular figure. The dimensions (e.g., physical structures) of the elements shown in the drawings described herein are not scaled.

As shown in FIG. 5A, FIG. 5B, and FIG. 6, memory device 200 can include a substrate 599 over which memory cells 210 through 215 and other memory cells (not shown) of memory device 200 can be formed. Transistors T1 and T2 of memory cell 210 can be formed vertically with respect to substrate 599. Substrate 599 can be a semiconductor substrate (e.g., silicon-based substrate) or other type of substrate. The Z-direction (e.g., vertical direction) is a direction perpendicular to (e.g., outward from) substrate 599. The Z-direction is also perpendicular to (e.g., extended vertically from) an X-direction and a Y-direction. The X-direction and Y-direction are perpendicular to each other.

As shown in FIG. 5A through FIG. 8, memory device 200 can include a conductive region 597 that can include a structure (e.g., a piece (e.g., a layer)) of material located over substrate 599. Example materials for conductive region 597 include a piece of metal, conductively doped polysilicon, or other conductive materials, or a combination of different conductive materials (e.g., different layers of conductive materials). Conductive region 597 can be part of (or can include) ground connection 297 (e.g., part of a ground plate) in FIG. 2 that can be coupled to a ground terminal (not shown) of memory device 200.

Conductive region 597 can be part of a common conductive structure (e.g., a common conductive region or conductive plate) that can be formed on a level of memory device 200 that is under the memory cells (e.g., memory cells 210 through 215) of memory device 200. In this example, the elements (e.g., part of transistors T1 and T2 or the entire transistors T1 and T2 schematically shown in FIG. 2) of each of the memory cells (e.g., memory cells 210 through 215) of memory device 200 can be formed (e.g., formed vertically) over the common conductive structure (e.g., a common conductive plate) and electrically coupled to the common conductive structure.

FIG. 5A through FIG. 8 show conductive region 597 as a single structure (e.g., single piece) as an example. However, conductive region 597 can be part of separate conductive structures (e.g., separate conductive strips) that can be formed on a level of memory device 200 that is under the memory cells (e.g., memory cells 210 through 215) of memory device 200. In such separate conductive structures of conductive region 597, the elements (e.g., part of transistors T1 and T2) of each of the memory cells (e.g., memory cells 210 through 215) of memory device 200 can be formed over (e.g., formed vertically) respective conductive structures (e.g., respective conductive strips) among the separate conductive structures (e.g., separate conductive strips) and electrically coupled to the respective conductive structures.

FIG. 5A through FIG. 8 show conductive region 597 contacting (e.g., directly coupled to) substrate 599 as an example. In an alternative structure, memory device 200 can include a dielectric (e.g., a layer of dielectric material, not shown) between conductive region 597 and substrate 599.

Some portions (e.g., gate oxide and cell isolation structures) of memory device 200 are omitted from FIG. 5A, FIG. 5B and FIG. 6 so as to not obscure the structure of the elements being shown in FIG. 5A, FIG. 5B and FIG. 6.

As shown in FIG. 5A through FIG. 8, each of data lines 221 and 222 (associated with signals BL1 and BL2, respectively) can have a length in the Y-direction, a width in the X-direction, and a thickness in the Z-direction. Each of data lines 221 and 222 can include a conductive material (or a combination of materials) that can be structured as a conductive line (e.g., conductive region). Example materials for data lines 221 and 222 include metal, conductively doped polysilicon, or other conductive materials.

Access line 241 (associated with signal WL1) can be structured by (can include) a combination of portions 541F and 541B (e.g., front and back conductive portions with respect to the Y-direction). Each of portions 541F and 541B can include a conductive material (or a combination of materials) that can be structured as a conductive line (e.g., conductive region) having a length extending continuously in the X-direction. Thus, portions 541F and 541B can be part of conductive lines that are opposite from each other (e.g., opposite from each other in the Y-direction).

Each of portions 541F and 541B can include a structure (e.g., a piece (e.g., a layer)) of conductive material (e.g., metal, conductively doped poly silicon, or other conductive materials). Each of portions 541F and 541B can have a length (shown in FIG. 5A, FIG. 5B) in the X-direction, a width (shown in FIG. 5A, FIG. 5B) in the Z-direction, and a thickness (shown in FIG. 8) in the Y-direction.

Portions 541F and 541B can be electrically coupled to each other. For example, memory device 200 can include a conductive material (e.g., not shown) that can contact (e.g., electrically couple to) portions 541F and 541B, such that portions 541F and 541B (which are part of a single access line 241) can be concurrently applied by the same signal (e.g., signal WL1).

In an alternative structure of memory device 200, either portion 541F or portion 541B can be omitted, such that access line 241 can include only either portion 541F or portion 541B. In the structure shown in FIG. 5A, FIG. 5B, including two portions 541F and 541B can help better control transistor T1 (e.g., transistor T1, shown schematically in FIG. 2) of each of memory cells 210 and 211 during a read operation.

As shown in FIG. 6, each of access lines 242 and 243 can also include different portions like access line 241. For example, access line 242 can include portions 542F and 542B, and access line 243 can include portions 543F and 543B.

As shown in FIG. 5A through FIG. 8, memory element 201 can be formed over (e.g., form on) conductive region 597. Memory element 201 can include a material different from the material of conductive portion 202. In an example, memory element 201 can include a piece (e.g., a layer) of material that can include a resistive material (e.g., a non-dielectric material), a chalcogenide material, or other non-dielectric materials. The material of memory element 201 can be configured to have different resistance states at different times. The value of information stored in memory element 201 can be based on the resistance state of the material of memory element 201. A write operation of memory device 200 can cause the material of memory element 201 to change from one resistance state to another resistance state based on the value of information stored in memory element 201.

As shown in FIG. 5A through FIG. 8, memory element 201 can be formed on different levels with other portions of memory cell 210 in the Z-direction. For example, as shown in FIG. 5A and FIG. 7, memory element 201 can be formed on a level that is different from the levels of memory cell 210 that include conductive portion 202, a material 520, and data line 221.

Conductive portion 202 can include a piece (e.g., a layer) of semiconductor material (e.g., polysilicon), a piece (e.g., a layer) of metal, or a piece of other conductive materials. The materials of conductive portion 202 can be different from the material of memory element 201. The materials of conductive portion 202 and portions 541F and 541B of access line 241 can be the same or can be different.

As shown in FIG. 5A, FIG. 5B, conductive portion 202 can include a portion (e.g., bottom portion) that is closer (e.g., extending in the Z-direction closer) to substrate 599 than each of portions 541F and 541B of access line 241.

FIG. 5A through FIG. 8 show an example where the top edge of conductive portion 202 is at a specific distance (e.g., distance shown in FIG. 5A, FIG. 5B) from the edge (e.g., bottom edge) of each of portions 541F and 541B of access line 241. However, the distance between the top edge of conductive portion 202 and the edge (e.g., bottom edge) of each of portions 541F and 541B may vary.

FIG. 5A through FIG. 8 show an example where portions 541F and 541B overlap (in the Z-direction) conductive portion 202. However, portions 541F and 541B may not overlap conductive portion 202.

As shown in FIG. 5A through FIG. 8, memory device 200 can include a portion that includes material 520 located between data line 221 and the portion that includes conductive portion 202. In this description, material 520 can also be called portion 520 or the portion that includes material 520. Thus, as shown in FIG. 5 through FIG. 8, memory cell 210 can include memory element 201 adjacent (e.g., formed over) conductive region 597, conductive portion 202 adjacent (e.g., formed over) memory element 201, and a portion (e.g., material 520) adjacent (e.g., formed over) conductive portion 202.

Material 520 can form a source (e.g., source terminal), a drain (e.g., drain terminal), a channel region (e.g., write channel region) between the source and the drain of transistor T2 of memory cell 210. Thus, as shown in FIG. 5A, FIG. 5B, the source, channel region, and the drain of transistor T2 of memory cell 210 can be formed from a single piece of the same material (or alternatively, a single piece of the same combination of materials) such as material 520. Therefore, the source, the drain, and the channel region of transistor T2 of memory cell 210 can be formed from the same material (e.g., material 520) of the same conductivity type (e.g., either n-type material or p-type material).

As shown in FIG. 7, memory device 200 can include material 521 that can form a source (e.g., source terminal), a drain (e.g., drain terminal), and a channel region (e.g., write channel region) between the source and the drain of transistor T2 of memory cell 211. Thus, as shown in FIG. 5A, FIG. 5B, the source, channel region, and the drain of transistor T2 of memory cell 211 can be formed from a single piece of the same material (or alternatively, a single piece of the same combination of materials) such as material 521.

Materials 520 and 521 can be the same. For example, each of materials 520 and 521 can include a structure (e.g., a piece (e.g., a layer)) of semiconductor material. In the example where transistor T2 is an NFET (as described above), materials 520 and 521 can include n-type semiconductor material (e.g., n-type silicon).

In another example, the semiconductor material that forms material 520 or material 521 can include a piece of oxide material. Examples of the oxide material used for materials 520 and 521 include semiconducting oxide materials, transparent conductive oxide materials, and other oxide materials.

As an example, each of materials 520 and 521 can include at least one of zinc tin oxide (ZTO), indium zinc oxide (IZO), zinc oxide (ZnOₓ), indium gallium zinc oxide (IGZO), indium gallium silicon oxide (IGSO), indium oxide (InOₓ, In₂O₃), tin oxide (SnO₂), titanium oxide (TiOx), zinc oxide nitride (ZnₓO_{y}N_{z}), magnesium zinc oxide (MgₓZn_{y}O_{z}), indium zinc oxide (InₓZn_{y}O_{z}), indium gallium zinc oxide (InₓGa_{y}Zn_{z}Oₐ), zirconium indium zinc oxide (ZrₓIn_{y}Zn_{z}Oₐ), hafnium indium zinc oxide (HfₓIn_{y}Zn_{z}Oₐ), tin indium zinc oxide (SnₓIn_{y}Zn_{z}Oₐ), aluminum tin indium zinc oxide (AlₓSn_{y}In_{z}ZnₐO_{d}), silicon indium zinc oxide (SiₓIn_{y}Zn_{z}Oₐ), zinc tin oxide (Zn_{z}Sn_{y}O_{z}), aluminum zinc tin oxide (AlₓZn_{y}Sn_{z}Oₐ), gallium zinc tin oxide (GaₓZn_{y}Sn_{z}Oₐ), zirconium zinc tin oxide (ZrₓZn_{y}Sn_{z}Oₐ), indium gallium silicon oxide (InGaSiO), and gallium phosphide (GaP).

The materials listed above are examples of materials 520 and 521. However, other materials different from the above-listed materials can be used. For example, other relatively high band-gap materials can be used. In another example, material 520 and 521 can include polysilicon.

As shown in FIG. 5A through FIG. 8, material 520 and conductive portion 202 of memory cell 210 can be adjacent each other and electrically coupled (e.g., directly coupled) to each other, such that material 520 can contact conductive portion 202 of memory cell 210 without an intermediate material (e.g., without a conductive material) between conductive portion 202 of memory cell 210 and material 520. In another example, material 520 can be electrically coupled to conductive portion 202 of memory cell 210, such that material 520 is not directly coupled to (not contacting) conductive portion 202 of memory cell 210, but material 520 is coupled to (e.g., indirectly contacting) conductive portion 202 of memory cell 210 through an intermediate material (e.g., a conductive material, not shown in FIG. 5A, FIG. 5B) between conductive portion 202 of memory cell 210 and material 520.

As shown in FIG. 5A through FIG. 7, memory cell 210 can include a portion 510 that is in electrical contact with conductive region 597 and the conductive region of data line 221. Portion 510 can include a structure (e.g., a piece (e.g., a layer)) of semiconductor material. Example materials for portion 510 include silicon, polysilicon (e.g., undoped or doped polysilicon), germanium, silicon-germanium, or other semiconductor materials, and semiconducting oxide materials (oxide semiconductors, e.g., SnO or other oxide semiconductors).

As described above with reference to FIG. 2, transistor T1 of memory cell 210 includes a channel region (e.g., read channel region). In FIG. 5A, FIG. 5B, the channel region of transistor T1 of memory cell 210 can include (e.g., can be formed from) portion 510. Portion 510 can be electrically coupled to data line 221 and conductive region 597. As described above with reference to FIG. 2, memory cell 210 can include a read path. In FIG. 5A, FIG. 5B, portion 510 (e.g., the read channel region of transistor T1 of memory cell 210) can be part of the read path of memory cell 210 that can carry a current (e.g., read current) during a read operation of reading information from memory cell 210. For example, during a read operation, to read information from memory cell 210, portion 510 can conduct a current (e.g., read current) between data line 221 and conductive region 597. The direction of the read current can be from data line 221 to conductive region 597 (through portions 510).

In the example where transistor T1 is a PFET and transistor T2 is an NFET, the material that forms portion 510 can have a different conductivity type from material 520 or 521. For example, portion 510 can include p-type semiconductor material (e.g., p-type silicon) regions, and materials 520 and 521 can include n-type semiconductor material (e.g., n-type gallium phosphide (GaP)) regions. In another example, portion 510 and the portion that includes material 520 (or material 521) can include materials of the same conductivity type (e.g., either type p-type or n-type).

As shown in FIG. 5A through FIG. 7, memory cell 210 can include a dielectric portion 515. Dielectric portion 515 can be gate oxide regions that electrically separate conductive portion 202 from portion 510, and electrically separate material 520 from portion 510. Dielectric portion 515 can include a side (e.g., vertical sidewall) 515S1 and a side (e.g., vertical sidewall) 515S2 opposite from side 515S1 in the X-direction. Memory element 201, conductive portion 202, and material 520 are adjacent (e.g., contacting) side 515S1 of dielectric portion 515. Portion 510 is adjacent (e.g., contacting) side 515S2 of dielectric portion 515 and is separated from memory element 201, conductive portion 202, and material 520 by dielectric portion 515. Example materials for dielectric portion 515 include silicon dioxide, hafnium oxide (e.g., HfO₂), aluminum oxide (e.g., Al₂O₃), or other dielectric materials. In an example structure of memory device 200, dielectric portion 515 includes a high-k dielectric material (e.g., a dielectric material having a dielectric constant greater than the dielectric constant of silicon dioxide). Using such a high-k dielectric material (instead of silicon dioxide) can improve the performance (e.g., reduce current leakage, increase drive capability of transistor T1, or both) of memory device 200.

As shown in FIG. 7, part of portion 541F can span across (e.g., overlap in the X-direction) part of portion 510 and part of material 520. As described above, portion 510 can form part of read channel region of transistor T1 and material 520 can form part of write channel region of transistor T2. Thus, as shown in FIG. 7, part of portion 541F can span across (e.g., overlap) part of (e.g., on a side (e.g., front side) in the Y-direction) both read and write channels of transistors T1 and T2, respectively. Although hidden from the view shown in FIG. 7 (but as can be seen in FIG. 5A, FIG. 5B), part of portion 541B can span across (e.g., overlap in the X-direction) part of (e.g., on another side (e.g., back side opposite from the front side) in the Y-direction) portion 510 and a part of material 520. As shown in FIG. 7, access line 241 can also span across (e.g., overlap in the X-direction) part of portion 511 (e.g., a portion of the read channel region of transistor T1 of memory cell 211) and part of material 521 (e.g., a portion of write channel region of transistor T2 of memory cell 211).

The spanning (e.g., overlapping) of access line 241 across portion 510 and material 520 allows access line 241 (a single access line) to control (e.g., to turn on or turn off) both transistors T1 and T2 of memory cell 210 and both transistors of memory cell 211. Similarly, the spanning (e.g., overlapping) of access line 241 across portion 511 and material 521 allows access line 241 (a single access line) to control (e.g., turn on or turn off) both transistors T1 and T2 of memory cell 211.

As shown in FIG. 7, memory device 200 can include dielectric material 526 that can form a structure (e.g., a dielectric) to electrically separate (e.g., isolate) parts of two adjacent (in the X-direction) memory cells of memory device 200. For example, dielectric material 526 can electrically separate material 520 (e.g., write channel region of transistor T2 of memory cell 210) from material 521 (e.g., write channel region of transistor T2 of memory cell 211) and electrically separate conductive portion 202 of memory cell 210 from conductive portion 202 of memory cell 211.

As shown in FIG. 7, memory device 200 can include a dielectric portion 531 and a dielectric portion 532 where memory cells 210 and 211 can be located between dielectric portions 531 and 532. Dielectric portion 531 can electrically isolate memory cell 210 from another memory cell (e.g., the memory cell on the left (not shown)) of memory cell 210. Dielectric portion 532 can electrically isolate memory cell 211 from another memory cell (e.g., the memory cell on the right (not shown)) of memory cell 211. The area bounded by dielectric portions 531 and 532 can be part of a trench (not labeled) formed during a process of forming memory device 200. Thus, memory cells 210 and 211 can be formed in part of a trench.

Some of portions (e.g., materials) of memory cells 210 and 211 can be formed adjacent (e.g., formed on) respective sidewalls (e.g., vertical portion with respect the Z-direction) of dielectric portions 531 and 532. For example, as shown in FIG. 7, portion 510 (e.g., semiconductor material portion) of memory cell 210 can be formed adjacent (e.g., formed on) a sidewall (not labeled) of dielectric portion 531. In another example, as shown in FIG. 7, portion 511 (e.g., semiconductor material portion) of memory cell 210 can be formed adjacent (e.g., formed on) a sidewall (not labeled) of dielectric portion 532.

As shown in FIG. 8, memory device 200 can include dielectric portions 518F and 518B (e.g., oxide regions) to electrically separate portions 541F and 541B of access line 241 from other elements (e.g., from portions 510 and 511 (e.g., read channel regions), conductive portion 202, and materials 520 and 521) of memory cells 210 and 211. The material (or materials) for dielectric portions 518F and 518B can be the same as (or alternatively, different from) the material (or materials) of dielectric portion 515. Example materials for portions 518F and 518B can include silicon dioxide, hafnium oxide (e.g., HfO₂), aluminum oxide (e.g., Al₂O₃), or other dielectric materials.

As shown in FIG. 8, portions 541F and 541B can be adjacent respective sides of material 520 and conductive portion 202 of memory cell 210. For example, portion 541F can be adjacent a side (e.g., right side in the X-direction in the view of FIG. 8) of a portion of each of material 520 and conductive portion 202. In another example, portion 541B can be adjacent another side (e.g., left side (opposite from the right side) in the X-direction in the view of FIG. 8) of a portion of each of material 520 and conductive portion 202.

As shown in FIG. 7, memory device 200 can include dielectric portions 551 adjacent respective data lines 221 and 222 and electrically separated from each other. Dielectric portions 551 can include a high-k dielectric material or other dielectric materials. Memory device 200 can include an air gap 552 between dielectric portions 551 between the data lines 221 and 222 to further provide electrical separation between data lines 221 and 222.

The above description focuses on the structure of memory cell 210. Memory cell 211 can include elements structured in ways similar to or the same as the elements of memory cell 210, described above. For example, as shown in FIG. 7, memory cell 211 can include conductive portion 202, channel region (e.g., write channel region) 521, portion 511 (e.g., read channel region), and dielectric portion 525. The material (or materials) for dielectric portion 525 can the same as the material (or materials) for dielectric portion 515.

As described above with reference to FIG. 2 through FIG. 8, the connection and structure of memory device 200 can allow a cross-point operation in that a memory cell (e.g., memory cell 210) of memory device 200 can be accessed using a single access line (e.g., access line 241) and a single data line (e.g., data line 221) during an operation (e.g., a read or write operation) of memory device 200. Such a cross-point operation can be achieved due in part to a terminal (e.g., a source terminal) of transistor T1 of each of the memory cells (e.g., memory cell 210 through 215) being coupled to a ground connection (e.g., ground connection 297). This ground connection allows a voltage level at a terminal (e.g., source terminal) of transistor T1 of a selected memory cell to remain unchanged (e.g., remain unswitched at 0V), thereby allowing the cross-point operation. The cross-point operation and the structure of memory device 200 can provide better memory performance in comparison with some conventional volatile memory devices (e.g., DRAM devices).

As described above, in the structure of the memory cell (e.g., memory cell 210 or 211 in FIG. 7), memory element 201 can be configured to include (e.g., to have) different resistance states to reflect different values of information stored in the memory cell. For example, a write operation of memory device 200 can cause memory element 201 to have one resistance state (e.g., resistance state “R0”) if information to be stored in that write operation has a value of “0” and another resistance state (e.g., resistance state “R1”) if information to be stored in that write operation has a value of “1”. Thus, memory element 201 can include one resistance state (e.g., resistance state R0) at a particular time based on information having a first value (e.g., “0”) stored in the memory element at that particular time, and another resistance state (e.g., resistance state R1) at another time based on information having another value (e.g., “1”) stored in the memory element at another time.

The voltages on the selected data line (e.g., data line 221) and the selected access line (e.g., access line 241) can be selected such that the resistance state (e.g., R0 or R1) of memory element 201 of a selected memory cell (e.g., memory cell 210) is not impacted (e.g., remain unchanged) during reading of the selected memory cell (e.g., memory cell 210).

Transistor T2 can be structured such that the value of its threshold voltage (Vt2) can depend on the resistance state (e.g., resistance state R0 or R1) of memory element 201, so that a current between a selected data line (e.g., data line 221) and conductive region 597 (e.g., part of ground connection 297) during a read operation can be either a relatively high current or low current (e.g., corresponding to the value of information stored in a selected memory cell). For example, the voltage on transistor T2 can be structured such that the voltage on conductive portion 202 can be either the same as the voltage on data line 221 if memory element 201 has one resistance state (e.g., resistance state R0) or 0V if memory element 201 has another resistance state (e.g., resistance state R1).

During a read operation of memory cell 210 (selected memory cell), transistor T1 (FIG. 7) of memory cell 210 can “fully” turn on responsive to the voltage on conductive portion 202 being the same as the voltage on data line 221 (e.g., if memory element 201 of memory cell 210 has resistance R0). A relatively high amount of current can flow from data line 221 (e.g., selected data line) to conductive region 597 through the channel region (e.g., portion 510 in FIG. 7) of transistor T1. Transistor T2 may “partially” turn on during a read operation when the voltage on conductive portion 202 is same as the voltage on data line 221 in a read operation. Thus, a relatively small current may also flow from data line 221 to conductive region 597 through memory element 201 of memory cell 210. However, the voltages for the selected data line (e.g., data line 221) and the selected access line (e.g., access line 241) such that the resistance state memory element 201 of the selected memory cell 210 remains unchanged. Thus, the value of information stored in memory element 201 of memory cell 210 remains unchanged. In this example, the high amount of current can be detected by detection circuitry of memory device 200 and translated into the value (e.g., “0”) of information stored in memory cell 210.

In another example, during a read operation of memory cell 210, transistors T1 and T2 (FIG. 7) of memory cell 210 can turn off responsive to the voltage on conductive portion 202 being 0V (e.g., if memory element 201 of memory cell 210 has resistance R1). Transistor T2 can also turn off responsive to the voltage on conductive portion 202 being 0V. A relatively small amount of current or zero current may be detected. In this example, the detection circuitry of memory device 200 can translate any detected current into the value (e.g., “1”) of information stored in memory cell 210.

Memory device 200 includes improvements and benefits over some conventional memory devices in that the structure of memory device 200 can improve retention of the value of information stored in the memory cell. For example, some memory devices may store information based on the amount of charge in a floating gate of a transistor of the memory cell. As described above, information can be stored in the form of a resistance state of memory element 201. Retention of information stored in the form of charge may face more challenges than retention of information stored in the form of a resistance state such as the resistance state of memory element 201.

Further, in some conventional memory devices (e.g., resistive memory device), current in both read and write operations flow through the same resistive element. This can constrain the operating range and selection of the material of the resistive element because the resistive element is part of both read and write operations. In memory device 200, current in a read operation mainly flows through a different path (instead of through memory element 201) such as through the read channel region (e.g., portion 510 in FIG. 7) of the read transistor (e.g., transistor T1 in FIG. 7). This allows a wider operating range for a selection for the material of memory elements 201 in comparison with the resistive element of some conventional memory devices.

FIG. 9A, FIG. 9B, and FIG. 9C show different views of a structure of a memory device 900 including multiple decks of memory cells, according to some embodiments described herein. FIG. 9A shows an exploded view (e.g., in the Z-direction) of memory device 900. FIG. 9B shows a side view (e.g., cross-sectional view) in the X-direction and the Z-direction of memory device 900. FIG. 9C shows a side view (e.g., cross-sectional view) in the Y-direction and the Z-direction of memory device 900.

As shown in FIG. 9A, memory device 900 can include decks (decks of memory cells) 905₀, 905₁, 905₂, and 905₃ that are shown separately from each other in an exploded view to help ease of viewing the deck structure of memory device 900. In reality, decks 905₀, 905₁, 905₂, and 905₃ can be attached to each other in an arrangement where one deck can be formed (e.g., stacked) over another deck over a substrate (e.g., a semiconductor (e.g., silicon) substrate) 999. For example, as shown in FIG. 9A, decks 905₀, 905₁, 905₂, and 905₃ can be formed in the Z-direction perpendicular to substrate 999 (e.g., formed vertically in the Z-direction with respect to substrate 999).

As shown in FIG. 9A, each of decks 905₀, 905₁, 905₂, and 905₃ can have memory cells arranged in the X-direction and the Y-direction (e.g., arranged in rows in the X-direction and in columns in the Y-direction). For example, deck 905₀ can include memory cells 910₀, 911₀, 912₀, and 913₀ (e.g., arranged in a row), memory cells 920₀, 921₀, 922₀, and 923₀ (e.g., arranged in a row), and memory cells 930₀, 931₀, 932₀, and 933₀ (e.g., arranged in a row).

Deck 905₁ can include memory cells 910₁, 911₁, 912₁, and 913₁ (e.g., arranged in a row), memory cells 920₁, 921₁, 922₁, and 923₁ (e.g., arranged in a row), and memory cells 930₁, 931₁, 932₁, and 933₁ (e.g., arranged in a row). Deck 905₂ can include memory cells 910₂, 911₂, 912₂, and 913₂ (e.g., arranged in a row), memory cells 920₂, 921₂, 922₂, and 923₂ (e.g., arranged in a row), and memory cells 930₂, 931₂, 932₂, and 933₂ (e.g., arranged in a row). Deck 905₃ can include memory cells 910₃, 911₃, 912₃, and 913₃ (e.g., arranged in a row), memory cells 920₃, 921₃, 922₃, and 923₃ (e.g., arranged in a row), and memory cells 930₃, 931₃, 932₃, and 933₃ (e.g., arranged in a row).

As shown in FIG. 9A, decks 905₀, 905₁, 905₂, and 905₃ can be located (e.g., formed vertically in the Z-direction) on levels (e.g., portions) 950, 951, 952, and 953, respectively, of memory device 900. The arrangement of decks 905₀, 905₁, 905₂, and 905₃ forms a 3-dimensional (3-D) structure of memory cells of memory device 900 in that different levels of the memory cells of memory device 900 can be located (e.g., formed) in different levels (e.g., different vertical portions) 950, 951, 952, and 953 of memory device 900.

Decks 905₀, 905₁, 905₂, and 905₃ can be formed one deck at a time. For example, decks 905₀, 905₁, 905₂, and 905₃ can be formed sequentially in the order of decks 905₀, 905₁, 905₂, and 905₃ (e.g., deck 905₁ is formed first and deck 905₃ is formed last). In this example, the memory cell of one deck (e.g., deck 905₁) can be formed either after formation of the memory cells of another deck (e.g., deck 905₀) or before formation of the memory cells of another deck (e.g., deck 905₂). Alternatively, decks 905₀, 905₁, 905₂, and 905₃ can be formed concurrently (e.g., simultaneously), such that the memory cells of decks 905₀, 905₁, 905₂, and 905₃ can be concurrently formed. For example, the memory cells in levels 950, 951, 952, and 953 of memory device 900 can be concurrently formed.

The structures of the memory cells of each of decks 905₀, 905₁, 905₂, and 905₃ can include the structures of the memory cells described above with reference to FIG. 1 through FIG. 8. For example, the structures of the memory cells of decks 905₀, 905₁, 905₂, and 905₃ can include the structure of the memory cells of memory device 200.

Memory device 900 can include data lines (e.g., bit lines) and access lines (e.g., word lines) to access the memory cells of decks 905₀, 905₁, 905₂, and 905₃. For simplicity, data lines and access lines of memory cells are omitted from FIG. 9A. However, the data lines and access lines of memory device 900 can be similar to the data lines and access lines, respectively, of the memory devices described above with reference to FIG. 1 through FIG. 8.

FIG. 9A shows memory device 900 including four decks (e.g., 905₀, 905₁, 905₂, and 905₃) as an example. However, the number of decks can be different from four. FIG. 9A shows each of decks 905₀, 905₁, 905₂, and 905₃ including one level (e.g., layer) of memory cells as an example. However, at least one of the decks (e.g., one or more of decks 905₀, 905₁, 905₂, and 905₃) can have two (or more) levels of memory cells. FIG. 9A shows an example where each of decks 905₀, 905₁, 905₂, and 905₃ includes four memory cells (e.g., in a row) in the X-direction and three memory cells (e.g., in a column) in the Y-direction. However, the number of memory cells in a row, in a column, or both, can vary.

The illustrations of apparatuses (e.g., memory devices 100, 200, and 900) and methods (e.g., operations of memory devices 100 and 200) are intended to provide a general understanding of the structure of various embodiments and are not intended to provide a complete description of all the elements and features of apparatuses that might make use of the structures described herein. An apparatus herein refers to, for example, either a device (e.g., any of memory devices 100, 200, and 900) or a system (e.g., an electronic item that can include any of memory devices 100, 200, and 900).

Any of the components described above with reference to FIG. 1 through FIG. 9C can be implemented in a number of ways, including simulation via software. Thus, apparatuses (e.g., memory devices 100, 200, and 900) or part of each of these memory devices described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

The memory devices (e.g., memory devices 100, 200, and 900) described herein may be included in apparatuses (e.g., electronic circuitry) such as high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 9C include apparatuses and methods of forming the apparatuses. One of the apparatuses includes a conductive region; a memory cell including a memory element, a first portion, a second portion, a dielectric portion, and a third portion; and a data line formed over the second and third portions of memory cell. The memory element is formed over the conductive region. The first portion is formed over the memory element and includes a first conductive material. The second portion is formed over the first portion and includes a second conductive material. The dielectric portion includes a first side adjacent the memory element, the first portion, and the second portion. The third portion includes a third conductive material and adjacent a second side of the dielectric portion and separated from the memory element, the first portion, and the second portion by the dielectric portion. Other embodiments, including additional apparatuses and methods, are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the terms “first”, “second”, and “third,” etc. are used merely as labels, and are not intended to impose numerical requirements on their objects.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
a conductive region;
a memory cell including:
a memory element formed over the conductive region;
a first portion formed over the memory element, the first portion including a first material;
a second portion formed over the first portion, the second portion including a second material;
a dielectric portion including a first side adjacent the memory element, the first portion, and the second portion; and
a third portion including a third material, the third portion adjacent a second side of the dielectric portion and separated from the memory element, the first portion, and the second portion by the dielectric portion; and
a data line formed over the second portion and the third portion.

2. The apparatus of claim 1, wherein the memory element includes a material configured to have different resistance states.

3. The apparatus of claim 1, wherein the memory element includes a material different from the first material.

4. The apparatus of claim 1, wherein the memory element includes a phase change material.

5. The apparatus of claim 1, wherein the first material includes polysilicon.

6. The apparatus of claim 1, wherein the second material includes a semiconducting oxide material.

7. The apparatus of claim 1, wherein the second material includes polysilicon.

8. The apparatus of claim 1, wherein the conductive region is part of a ground plate of the apparatus.

9. The apparatus of claim 1, further comprising an additional memory cell, wherein the memory cell is included in a first deck of memory cells of a memory device of the apparatus, and the additional memory cell is included in a second deck of additional memory cells of the memory device.

10. An apparatus comprising:
a data line;
a memory cell coupled to the data line, the memory cell including:
a first transistor including a first channel region coupled to the data line, and a conductive portion separated from the first channel region by a dielectric portion;
a second transistor including a second channel region coupled to the conductive portion and the data line; and
a memory element coupled to the conductive portion, the memory element and the conductive portion having different materials; and
a ground connection coupled to the memory element and the first channel region of the first transistor.

11. The apparatus of claim 10, wherein the memory element is configured to store information, and a value of the information is based on a resistance state of the memory element.

12. The apparatus of claim 10, wherein the first channel region includes polysilicon.

13. The apparatus of claim 10, wherein the second channel region includes at least one of zinc tin oxide (ZTO), indium zinc oxide (IZO), zinc oxide (ZnOₓ), indium gallium zinc oxide (IGZO), indium gallium silicon oxide (IGSO), indium oxide (InOₓ, In₂O₃), tin oxide (SnO₂), titanium oxide (TiOx), zinc oxide nitride (ZnₓO_{y}N_{z}), magnesium zinc oxide (MgₓZn_{y}O_{z}), indium zinc oxide (InₓZn_{y}O_{z}), indium gallium zinc oxide (InₓGa_{y}Zn_{z}Oₐ), zirconium indium zinc oxide (ZrₓIn_{y}Zn_{z}Oₐ), hafnium indium zinc oxide (HfₓIn_{y}Zn_{z}Oₐ), tin indium zinc oxide (SnₓIn_{y}Zn_{z}Oₐ), aluminum tin indium zinc oxide (AlₓSn_{y}In_{z}ZnₐO_{d}), silicon indium zinc oxide (SiₓIn_{y}Zn_{z}Oₐ), zinc tin oxide (ZnₓSn_{y}O_{z}), aluminum zinc tin oxide (AlₓZn_{y}Sn_{z}Oₐ), gallium zinc tin oxide (GaₓZn_{y}Sn_{z}Oₐ), zirconium zinc tin oxide (ZrₓZn_{y}Sn_{z}Oₐ), indium gallium silicon oxide (InGaSiO), and gallium phosphide (GaP).

14. The apparatus of claim 10, wherein the first channel region and the second channel region have a same conductivity type.

15. The apparatus of claim 10, wherein the first channel region and the second channel region have different conductivity types.

16. The apparatus of claim 10, wherein the first and second transistors have different threshold voltages.

17. The apparatus of claim 10, wherein the second transistor has a threshold voltage greater than a threshold voltage of the first transistor.

18. The apparatus of claim 10, wherein the memory element includes ferromagnetic plates.

19. An apparatus comprising:
a first conductive region located in a first level of the apparatus;
a second conductive region located in a second level of the apparatus;
a memory cell located between the first and second levels and coupled to the first and second conductive regions, the memory cell including:
a memory element adjacent the first conductive region;
a first portion adjacent the memory element;
a second portion adjacent the first portion, the first and second portions having different materials; and
a semiconductor material portion in electrical contact with the first and second conductive regions; and
a conductive line electrically separated from the memory element, the first portion, the second portion, and the semiconductor material portion, part of the conductive line spanning across part of the semiconductor material portion and the second portion.

20. The apparatus of claim 19, wherein:
the memory element includes a first resistance state at a first time based on information having a first value stored in the memory element at the first time; and
the memory element includes a second resistance state at a second time based on information having a second value stored in the memory element at the second time.

21. The apparatus of claim 19, wherein the memory element includes a non-dielectric material.

22. The apparatus of claim 19, wherein the semiconductor material portion includes p-type material and the second portion includes n-type material.

23. The apparatus of claim 19, wherein the semiconductor material portion and the second portion include n-type material.

24. The apparatus of claim 19, wherein the second conductive region is part of a data line of the apparatus, and the conductive line is part of a word line of the apparatus.

25. The apparatus of claim 19, wherein the first conductive region is part of a ground connection of the apparatus.
